(19) United States
(12) Patent Application Publication
(10) Pub. No.: US 2024/0286060 A1
(43) Pub. Date: Aug. 29, 2024

(54) CONCENTRATION CONTROL DEVICE, RAW MATERIAL VAPORIZATION SYSTEM, CONCENTRATION CONTROL METHOD, AND RECORDING MEDIUM STORING CONCENTRATION CONTROL PROGRAM

(71) Applicant: HORIBA STEC, Co., Ltd., Kyoto-shi (JP)

(72) Inventor: Kotaro TAKIJIRI, Kyoto-shi (JP)

(21) Appl. No.: 18/588,463

(22) Filed: Feb. 27, 2024

(30) Foreign Application Priority Data
Feb. 28, 2023 (JP) 2023-029849

(51) Int. Cl. B01D 1/00

(52) U.S. Cl. CPC B01D 1/0082

(57) ABSTRACT

A concentration control device enables concentration control at high speed and with suppressed overshoot and is used in a raw material vaporization system that introduces a carrier gas into a liquid or solid raw material contained in a vaporization tank, vaporizes the carrier gas, and supplies a raw material gas generated by vaporization. The concentration control device includes flow rate control equipment that controls a flow rate of the carrier gas, a concentration measurement unit that measures a concentration of the raw material gas, and a flow rate control unit that controls a flow rate operation amount input to the flow rate control equipment by model predictive control based on a target concentration value of the raw material gas and a measured concentration value of the concentration measurement unit.

The present application claims priority to Japan Patent Application No. 2023-029849 filed Feb. 28, 2023, which is incorporated herein by reference in its entirety.

### BACKGROUND OF THE INVENTION

### 1. Technical Field

The present invention relates to a concentration control device, a raw material vaporization system, a concentration control method, and a recording medium storing a concentration control program.

### 2. Description of the Related Art

In a cleaning step of a semiconductor manufacturing process, it is a problem to reduce a watermark generated when a wafer is dried. In addition, in a drying step, isopropyl alcohol (IPA) is sprayed onto the wafer together with a carrier gas such as nitrogen, and then the wafer is dried. Thus, in recent years, concentration control thereof has become important. Further, in the concentration control, the temperature of a vaporization tank that stores a raw material and the flow rate of the carrier gas such as nitrogen are made constant, but real-time concentration control is important due to an increase in demand for process reproducibility.

Here, in a conventional raw material vaporization system, as described in JP 4034344 B2, for example, it is considered that the concentration of IPA is measured by an analyzer using non-dispersive infrared absorption spectroscopy (NDIR), and the flow rate of the carrier gas is controlled by proportional, integral, and derivative (PID) control.

However, due to a dead time of the response caused by gas replacement in a pipe, adjustment of the PID is necessary in order to satisfy a desired response time. Thus, it is difficult to determine feasible response performance, and an increase in the number of adjustment steps of the PID becomes a problem.

### PRIOR ART DOCUMENT

### Patent Document

JP 4034344 B2

### SUMMARY OF THE INVENTION

Therefore, the present invention has been made to solve the above-described problem, and an object of the present invention is to reduce the number of control parameter adjustment steps while improving the response performance.

That is, a concentration control device of the present invention is a concentration control device that is used in a raw material vaporization system that introduces a carrier gas into a liquid or solid raw material contained in a vaporization tank, vaporizes the carrier gas, and supplies a raw material gas generated by vaporization, the concentration control device including flow rate control equipment that controls a flow rate of the carrier gas, a concentration measurement unit that measures a concentration of the raw material gas, and a flow rate control unit that controls a flow rate operation amount input to the flow rate control equipment by model predictive control based on a target concentration value of the raw material gas and a measured concentration value of the concentration measurement unit.

In such a concentration control device, since the flow rate operation amount input to the flow rate control equipment is controlled by the model predictive control, the response performance can be improved as compared with the conventional PID control. Further, in the model predictive control, it is sufficient to conduct one identification experiment of a control target, and optimization of a parameter in the PID control becomes unnecessary. Therefore, adjustment man-hours can be greatly reduced.

The flow rate control unit desirably uses, as a prediction model of the model predictive control, a model including a dead time based on a time of arrival of the raw material gas at the concentration measurement unit provided in a raw material gas lead-out path.

With this configuration, concentration control can be made at high speed and with suppressed overshoot by the model predictive control in consideration of a response dead time caused by gas replacement in the raw material gas lead-out path.

The flow rate control unit desirably makes a time constant of a reference trajectory related to the concentration of the raw material gas larger than a time constant of a system included in the prediction model of the model predictive control.

With this configuration, since the time constant of the reference trajectory is later than the time constant of the control target, the flow rate operation amount can be controlled so that the prediction trajectory of the control target matches with the reference trajectory.

In addition, the raw material vaporization system of the present invention includes a vaporization tank that stores a liquid or solid raw material, a carrier gas supply path for supply of a carrier gas to the vaporization tank, a raw material gas lead-out path for leading-out of a raw material gas obtained by vaporizing the raw material from the vaporization tank, and the above-described concentration control device.

Further, a concentration control method of the present invention is a concentration control method that is used in a raw material vaporization system that introduces a carrier gas into a liquid or solid raw material contained in a vaporization tank, vaporizes the carrier gas, and supplies a raw material gas generated by vaporization, the concentration control method including controlling a flow rate of the carrier gas using flow rate control equipment, measuring a concentration of the raw material gas with a concentration measurement unit, and controlling a flow rate operation amount input to the flow rate control equipment by model predictive control based on a target concentration value of the raw material gas and a measured concentration value of the concentration measurement unit.

In addition, a concentration control program of the present invention is a concentration control program that controls a concentration of a raw material gas in a raw material vaporization system that introduces a carrier gas into a liquid or solid raw material contained in a vaporization tank, vaporizes the carrier gas, and supplies a raw material gas generated by vaporization, the concentration control program being used in a concentration control device including flow rate control equipment that controls a flow rate of the carrier gas and a concentration measurement unit that measures the concentration of the raw material gas, the concentration control program causing a computer to have a function as a flow rate control unit that controls a flow rate operation amount input to the flow rate control equipment by model predictive control based on a target concentration value of the raw material gas and a measured concentration value of the concentration measurement unit.

Note that the concentration control program may be distributed electronically or may be recorded in a program recording medium such as a compact disc (CD), a digital versatile disc (DVD), or a flash memory.

As described above, the present invention can make it possible to reduce the number of steps of adjusting control parameters while improving response performance.

### BRIEF DESCRIPTION OF THE DRAWINGS

FIG. 1 is a diagram schematically illustrating a configuration of a raw material vaporization system according to an embodiment of the present invention;

FIG. 2 is a diagram illustrating a mechanism of model predictive control according to the embodiment;

FIG. 3 is a diagram illustrating a response result of concentration of a raw material gas (isopropyl alcohol (IPA)) in a case where a carrier gas is caused to flow stepwise;

FIG. 4 is a control block diagram where concentration is controlled by conventional proportional, integral, and derivative (PID) control;

FIG. 5 is a diagram illustrating an experimental result of concentration control by the conventional PID control;

FIG. 6 is a diagram illustrating an experimental result obtained after PID parameters are adjusted in the conventional PID control;

FIG. 7 is a diagram showing an algorithm with which concentration control is made by using a model perspective controller (MPC) according to the embodiment; and

FIG. 8 is a diagram illustrating an experimental result of the concentration control using the MPC according to the embodiment.

### DETAILED DESCRIPTION

Hereinafter, an embodiment of a raw material vaporization system incorporating a concentration control device of the present invention will be described with reference to the drawings. Note that any of the drawings to be referred below is schematically drawn in an omitted or exaggerated manner appropriately for easy understanding. The same components are denoted by the same reference symbols, and the description thereof will be omitted as appropriate.

### <1. Basic Configuration of Raw Material Vaporization System 100>

The raw material vaporization system 100 of the present embodiment is used in a semiconductor manufacturing apparatus that executes a semiconductor manufacturing process such as a drying step, and supplies a concentration-controlled raw material gas to, for example, a chamber where the drying step is performed.

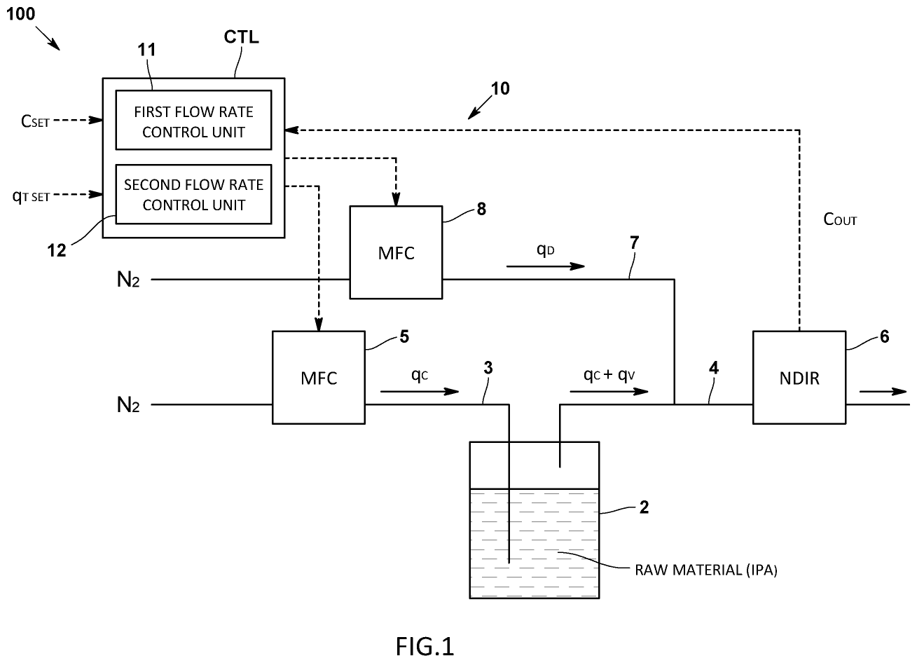

Specifically, as illustrated in FIG. 1, the raw material vaporization system 100 includes a vaporization tank 2 that stores a liquid or solid raw material such as isopropyl alcohol (IPA), a carrier gas supply path 3 for supply of a carrier gas such as nitrogen (N₂) to the vaporization tank 2, a raw material gas lead-out path 4 for leading-out of the raw material gas obtained by vaporizing the raw material from the vaporization tank 2, first flow rate control equipment 5 provided in the carrier gas supply path 3, and a concentration measurement unit 6 provided in the raw material gas lead-out path 4.

Here, the first flow rate control equipment 5 is a mass flow controller including a flow rate sensor and a fluid control valve. The flow rate sensor may be of a differential pressure type, a thermal type, or the like. Further, the valve opening degree of the fluid control valve is controlled by a valve control unit (not illustrated) based on a measured flow rate value of the flow rate sensor and a flow rate operation amount q_{C SET} output by a first flow rate control unit 11, described later.

Further, the concentration measurement unit 6 uses non-dispersive infrared absorption spectroscopy (NDIR). Specifically, the concentration measurement unit 6 includes a measurement cell into which a raw material gas is introduced, an infrared light source that irradiates the measurement cell with infrared light, an infrared detector that detects the infrared light having passed through the measurement cell, and a concentration calculation unit that calculates the concentration of the raw material gas based on a light intensity signal detected by the infrared detector.

Note that the first flow rate control equipment 5, the concentration measurement unit 6, and the first flow rate control unit 11, described later, constitute a concentration control device 10 of the present invention.

In the present embodiment, a diluent gas supply path 7 for supply of a diluent gas for diluting a raw material gas is connected to the raw material gas lead-out path 4, and second flow rate control equipment 8 that controls the flow rate of the diluent gas is provided in the diluent gas supply path 7.

Here, the second flow rate control equipment 8 is a mass flow controller including a flow rate sensor and a fluid control valve. The flow rate sensor may be of a differential pressure type, a thermal type, or the like. Further, the valve opening degree of the fluid control valve is controlled by a valve control unit (not illustrated) based on a measured flow rate value of the flow rate sensor and a flow rate operation amount q_{D SET} output by a second flow rate control unit 12, described later.

The raw material vaporization system 100 includes a control device CTL that causes the first flow rate control equipment 5 to control the concentration cour of the raw material gas based on the concentration measured value cour of the raw material gas measured by the concentration measurement unit 6 and the target concentration value CSET. In addition, the control device CTL of the present embodiment makes control so that a total flow rate (q_{C}+q_{D}) of the flow rate q_{c} of the carrier gas supplied to the vaporization tank 2 and the flow rate qp of the diluent gas supplied from the diluent gas supply path 7 to the raw material gas lead-out path 4 becomes constant.

### <2. Specific Configuration of Control Device CTL>

The control device CTL of the present embodiment is a so-called computer including a central processing unit (CPU), a memory, an analog-digital (A/D) converter, a digital-analog (D/A) converter, and various input-output devices. The concentration control program stored in the memory is executed, and various devices cooperate with each other to function as the first flow rate control unit 11 that controls the operation of the first flow rate control equipment 5 and the second flow rate control unit 12 that controls the operation of the second flow rate control equipment 8.

The first flow rate control unit 11 controls a flow rate operation amount q_{C SET} input to the first flow rate control equipment 5 using a model predictive controller (MPC) based on the target concentration value CSET of the raw material gas and the measured concentration value cour of the concentration measurement unit 6.

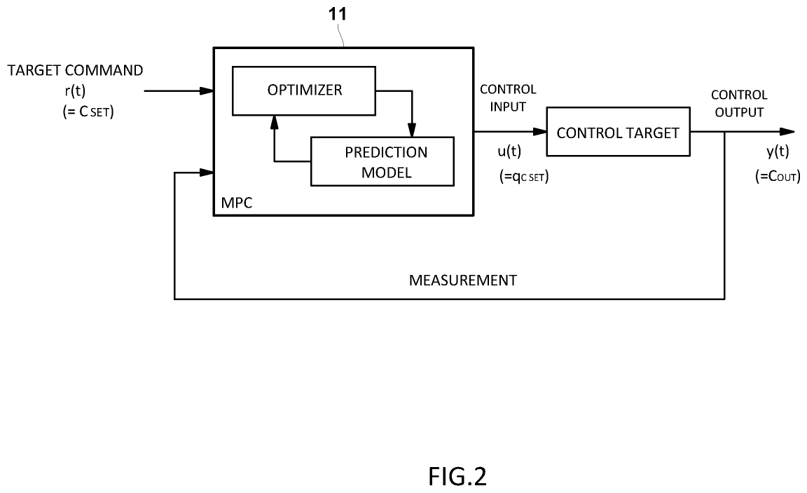

Here, as illustrated in FIG. 2, the model predictive controller is a control method for performing optimization while predicting a future response at each time. With this method, a future behavior over a finite section from a current time of a control target is predicted by providing a prediction model (control target model) in the first flow rate control unit 11.

In FIG. 2, a target command r(t) is the target concentration value CSET of the raw material gas, a control input u(t) is the flow rate operation amount q_{C}ET input to the first flow rate control equipment 5, and a control output y(t) is the concentration c_{OUT} of the raw material gas measured by the concentration measurement unit 6. The concentration measured value cour measured from the control target is applied to the prediction model inside the first flow rate control unit 11, and a new control input u(t) is determined so that a tracking error from the current time to a predetermined time is minimized by an optimizer.

The first flow rate control unit 11 uses, as the prediction model of the model predictive controller, a model including a dead time based on a time of arrival of the raw material gas at the concentration measurement unit 6 provided in the raw material gas lead-out path 4. This dead time is a dead time of a response caused by gas replacement in the raw material gas lead-out path 4 between the vaporization tank 2 and the concentration measurement unit 6. The dead time will be described later in detail.

The first flow rate control unit 11 makes a time constant of a reference trajectory related to the concentration of the raw material gas larger than a time constant of the system (transfer function) included in the prediction model of the model predictive control. Details of the time constant of the system (transfer function) and the time constant of the reference trajectory will be described later.

The second flow rate control unit 12 controls the flow rate operation amount q_{D} SET input to the second flow rate control equipment 8 so that the total flow rate (q_{C}+q_{D}) of the carrier gas flow rate q_{c} and the diluent gas flow rate q_{D} becomes constant. Specifically, the second flow rate control unit 12 sets the difference (q_{T SET}−q_{C SET}) between a total flow rate setting value q_{T SET} of the carrier gas and the diluent gas and the flow rate operation amount q_{C SET} of the first flow rate control equipment 5 as the flow rate operation amount q_{D SET} (set flow rate value of the diluent gas) of the second flow rate control equipment 8.

Hereinafter, the concentration control by the conventional proportional, integral, and derivative (PID) control and the concentration control by the MPC of the control device CTL of the present embodiment will be described in detail.

### <3. Control Target>

The control target is illustrated in FIG. 1. The physical quantities desired to be controlled are the concentration measured value cour measured by the concentration measurement unit 6 and the total flow rate q_{T} (total flow rate of the carrier gas flow rate q_{c} and the diluent gas flow rate q_{D}).

Here, a mass flow controller is used for the flow rate control, and the response performance of the flow rate of the mass flow controller has sufficiently higher-speed responsiveness than the responsiveness of concentration output.

The concentration cour of the raw material gas (IPA) is measured by the concentration measurement unit 6 (NDIR), and can be expressed by the following expression. The carrier gas flow rate q_{C} is used as the operation amount, but since the flow rate is in the denominator, the concentration c_{OUT} has a characteristic having nonlinearity. Note that in the following expression, qv indicates the raw material gas flow rate.

$${c}_{OUT} = \frac{{q}_{V}}{{q}_{C} + {q}_{V} + {q}_{D}} \times 100 \qquad [ Mathematical expression 1 ]$$

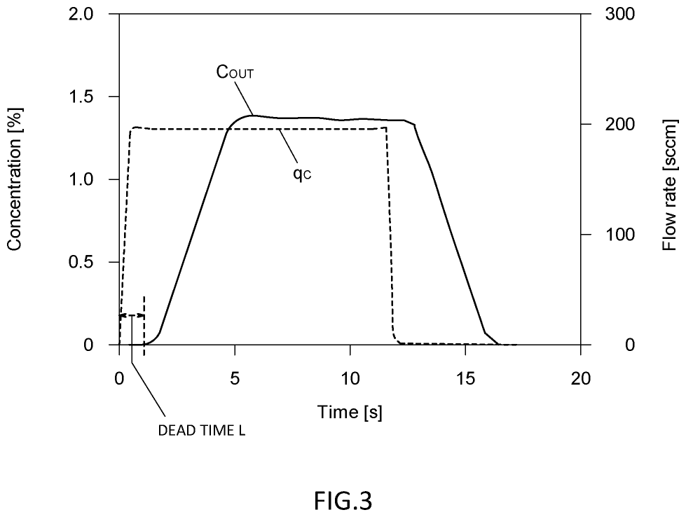

FIG. 3 illustrates a response result of the concentration c_{OUT}. Here, the concentration c_{OUT} is a concentration in a case where the carrier gas flows stepwise without performing concentration control. The flow rate of the carrier gas is set to 200 sccm that is close to an actual operation condition.

The identification is performed based on this experimental result, and the following transfer function P(s) is obtained. The transfer function P(s) includes a dead time of about 1 second, and this dead time makes it difficult to adjust the response of the concentration control.

$$P ( s ) = \frac{0.055 \cdot s + 1}{1.84 \cdot {s}^{2} + 1.75 \cdot s + 1} 0.0069 {e}^{- s} \qquad [ Mathematical expression 2 ]$$

The transfer function P(s) is obtained by calculating coefficients a₁, b₁, b₂, and L of the following general expression based on the response result illustrated in FIG. 3. Note that the coefficient L indicates a dead time. In addition, q_{C} indicates the carrier gas flow rate in FIG. 3, qv indicates the raw material gas flow rate in FIG. 3, and q_{D} indicates the diluent gas flow rate in FIG. 3.

$$P ( s ) = \frac{{a}_{1} \cdot s + 1}{{b}_{2} \cdot {s}^{2} + {b}_{1} \cdot s + 1} \frac{{q}_{V}}{{q}_{C} + {q}_{V} + {q}_{D}} {e}^{- sL} {q}_{C} \qquad [ Mathematical expression 3 ]$$

### <4. Concentration Control by PID Control>

As target settings, two settings of the target concentration value CSET of the raw material gas and the total flow rate setting value q_{T SET} are input to the control device CTL. As for the response, the concentration cour of the raw material gas and the total flow rate q_{T} of the carrier gas are desirably converged within 10 seconds to reduce the overshoot as much as possible.

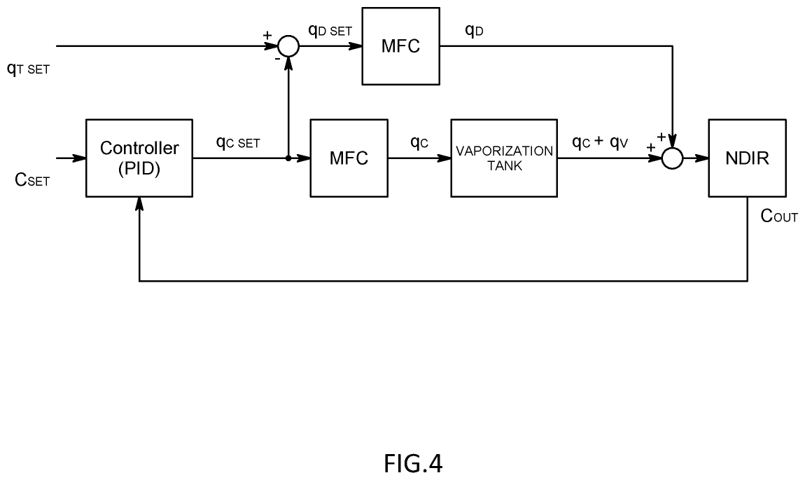

FIG. 4 illustrates a block diagram of a PID control system. In the conventional method, the control device CTL makes PID control, and calculates the flow rate target value q_{C SET} of the carrier gas to control the concentration cour of the raw material gas.

The carrier gas total flow rate setting value q_{T SET} is the sum of the flow rate target value q_{C SET} of the carrier gas and the set flow rate value q_{D SET} of the diluent gas expressed by the following equation. Therefore, the total flow rate control of the control system is configured to set the difference between q_{T SET} and q_{C SET} to the set flow rate value q_{D SET} of the diluent gas.

$${q}_{T SET} = {q}_{C SET} + {q}_{D SET} \qquad [ Mathematical expression 4 ]$$

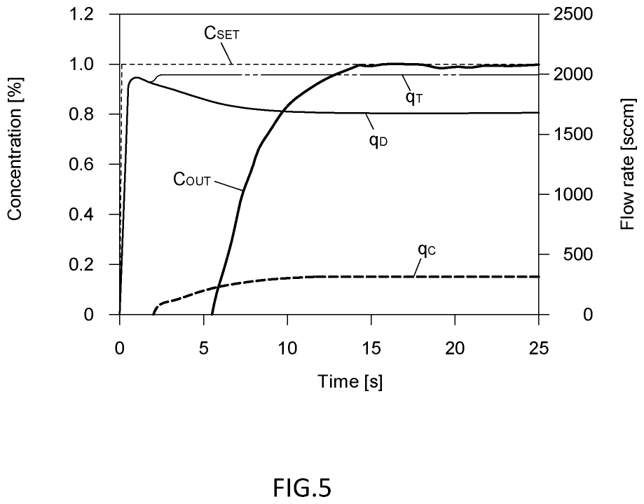

FIG. 5 illustrates an experimental result of the PID control using the conventional method. Here, a step response experiment is conducted with the target concentration value (concentration setting value) CSET of the raw material gas being set to 1% and the target total flow rate value (total flow rate setting value) q_{T SET} being set to 2000 sccm.

As a result of adjusting the PID parameter, the total flow rate is stable in about 2 seconds after the setting. However, the concentration output has a convergence time of about 15 seconds.

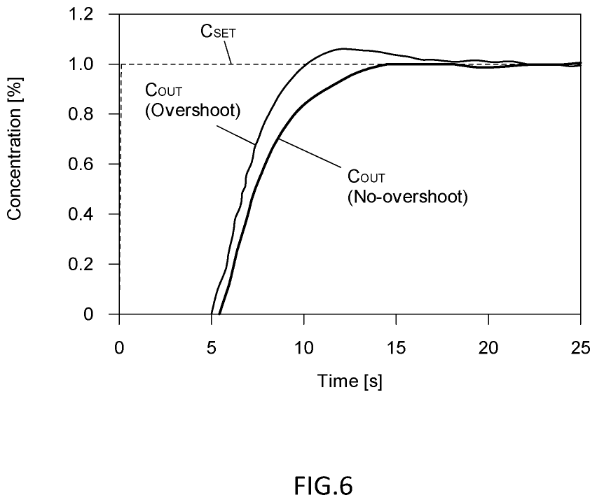

The PID is further adjusted so that a response reaches 10 seconds. The results are shown in FIG. 6. In the PID control, when the response time is tried to be adjusted to 10 seconds, overshoot increases. This is considered to be because a dead time is included in the control target.

### <5. Concentration Control by MPC>

Next, the concentration control by the MPC will be described. Note that the control of the total flow rate q_{T} is similar to the conventional PID control.

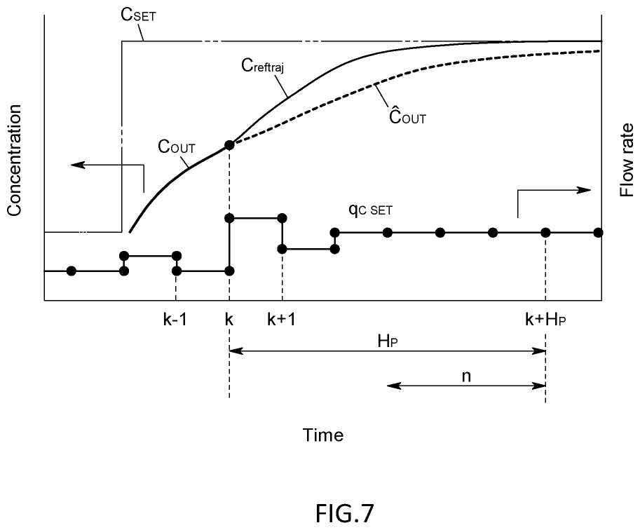

FIG. 7 illustrates an algorithm of the MPC of the first flow rate control unit 11. Here, k indicates a time discretized by a sampling period Tₛ.

When the number of prediction horizon points (time for predicting a future) is indicated by H_{P}, the reference trajectory c_{reftraj}(k+i|k) (i=1, . . . , H_{P}) indicates an ideal trajectory, and its response time is determined based on the time constant T_{ref}.

$${c}_{reftraj} ( k + i \vert k ) = {c}_{OUT} ( k ) {e}^{- \frac{i \cdot {T}_{s}}{{T}_{ref}}} + {c}_{SET} ( 1 - {e}^{- \frac{i \cdot {T}_{s}}{{T}_{ref}}} ) \qquad [ Mathematical expression 5 ]$$

The prediction trajectory c∧_{OUT} (k+i|k) (the superscript ∧ indicates the predicted value) in a case where the operation amount Δq_{C SET} is given is expressed by the following expression from a free response c_{free} (k+i|k) under the current operation amount and a unit step response S(i) calculated from the above mathematical expression 2.

$${\hat{c}}_{out} ( k + i \vert k ) = {c}_{free} ( k + i \vert k ) = S ( i ) Δ {q}_{C SET} \qquad [ Mathematical expression 6 ]$$

The operation amount Δq_{C SET} is determined for each sampling period Tₛ so that the reference trajectory c_{reftraj}(k+i|k) and the prediction trajectory c∧_{OUT} (k+i|k) coincide with each other at the last n point of a prediction horizon, and the flow rate target value q_{C SET} at the next sampling period is determined.

$${q}_{C SET} ( k ) = {q}_{C SET} ( k - 1 ) + Δ {q}_{C SET} \qquad [ Mathematical expression 7 ]$$

Next, MPC is mounted, and a concentration control experiment is conducted. The time constant, the prediction horizon, and the data interval of the prediction trajectory are as follows.
Sampling period Tₛ[s]: 0.1
Time constant T_{ref}[s] of prediction trajectory: 2
Number of prediction horizon points H_{P}[s]: 5
Data interval n: 5

Further, an experiment is conducted with the target concentration value (concentration setting value) CSET of the raw material gas being 1% and the target total flow rate value (total flow rate setting value) q_{T SET} being 2000 sccm.

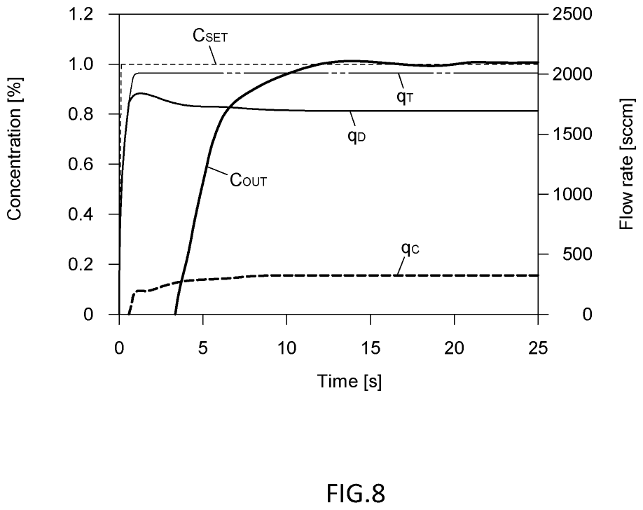

The experimental result is shown in FIG. 8. As seen from FIG. 8, the convergence time of the concentration control is about 10 seconds due to the concentration control using the MPC, and the overshoot is reduced. Further, the total flow rate converges in about 1 second, and the convergence time can be shortened as compared with the conventional method.

### 6. Effects of Present Embodiment

As described above, in the raw material vaporization system 100 in the present embodiment, since the flow rate operation amount q_{C SET} input to the first flow rate control equipment 5 is controlled by the model predictive control, the response performance can be improved as compared with the conventional PID control. Further, in the model predictive control, it is sufficient to conduct one identification experiment of a control target, and optimization of a parameter in the PID control becomes unnecessary. Therefore, adjustment man-hours can be greatly reduced.

In addition, since the model including the dead time based on the time of arrival at the concentration measurement unit 6 provided in the raw material gas lead-out path 4 is used as the prediction model of the model predictive control, concentration control can be performed at high speed and with suppressed overshoot by the model predictive control in consideration of the dead time of the response due to gas replacement in the raw material gas lead-out path 4.

Further, since the time constant of the reference trajectory related to the concentration of the raw material gas is made larger than the time constant of the system included in the prediction model of the model predictive control, the flow rate operation amount can be controlled so that the prediction trajectory of the control target matches with the reference trajectory.

### 7. Other Embodiments

For example, the raw material of the above embodiment is a liquid raw material such as isopropyl alcohol, but may be a solid raw material.

Further, the vaporization method may be other vaporization methods such as a heating method in addition to a bubbling method.

Further, in the above embodiment, the total flow rate of the carrier gas flow rate and the diluent gas flow rate is made constant, but the total flow rate may not be made constant.

Furthermore, in the above embodiment, the diluent gas supply path is provided to dilute the raw material gas, but the diluent gas supply path may not be provided.

In addition, the time constant of the system included in the prediction model of the model predictive control may be identical to the time constant of the reference trajectory related to the concentration of the raw material gas.

In addition, the concentration control device of the above embodiment supplies a raw material gas to a chamber of a semiconductor manufacturing apparatus, but may supply a raw material gas to another chamber.

Further, the concentration control device of the above embodiment is incorporated in the raw material vaporization system, but may be a device (module) different from the raw material vaporization system.

In addition, various modifications and combinations of the embodiments may be made without departing from the gist of the present invention.

### REFERENCE CHARACTERS LIST

100 raw material vaporization system
10 concentration control device
2 vaporization tank
3 carrier gas supply path
4 raw material gas lead-out path
5 first mass flow controller (first flow rate control equipment)
6 concentration measurement unit
7 diluent gas supply path
8 second mass flow controller (second flow rate control equipment)
CTL control device
11 first flow rate control unit
12 second flow rate control unit

What is claimed is:

1. A concentration control device that is used in a raw material vaporization system that introduces a carrier gas into a liquid or solid raw material contained in a vaporization tank, vaporizes the carrier gas, and supplies a raw material gas generated by vaporization, the concentration control device comprising:
flow rate control equipment that controls a flow rate of the carrier gas;
a concentration measurement unit that measures a concentration of the raw material gas; and
a flow rate control unit that controls a flow rate operation amount input to the flow rate control equipment by model predictive control based on a target concentration value of the raw material gas and a measured concentration value of the concentration measurement unit.

2. The concentration control device according to claim 1, wherein the flow rate control unit uses, as a prediction model of the model predictive control, a model including a dead time based on a time of arrival of the raw material gas at the concentration measurement unit provided in a raw material gas lead-out path.

3. The concentration control device according to claim 1, wherein the flow rate control unit makes a time constant of a reference trajectory related to the concentration of the raw material gas larger than a time constant of a system included in a prediction model of the model predictive control.

4. A raw material vaporization system comprising:
a vaporization tank that stores a liquid or solid raw material;
a carrier gas supply path for supply of a carrier gas to the vaporization tank;
a raw material gas lead-out path for leading-out of a raw material gas obtained by vaporizing the raw material from the vaporization tank; and
the concentration control device according to claim 1.

5. A concentration control method that is used in a raw material vaporization system that introduces a carrier gas into a liquid or solid raw material contained in a vaporization tank, vaporizes the carrier gas, and supplies a raw material gas generated by vaporization, the concentration control method comprising:
controlling a flow rate of the carrier gas using flow rate control equipment;
measuring a concentration of the raw material gas using a concentration measurement unit; and
controlling a flow rate operation amount input to the flow rate control equipment by model predictive control based on a target concentration value of the raw material gas and a measured concentration value of the concentration measurement unit.

6. A recording medium storing a concentration control program that controls concentration of a raw material gas in a raw material vaporization system that introduces a carrier gas into a liquid or solid raw material contained in a vaporization tank, vaporizes the carrier gas, and supplies the raw material gas generated by vaporization, the concentration control program being used in a concentration control device including flow rate control equipment that controls a flow rate of the carrier gas, and a concentration measurement unit that measures the concentration of the raw material gas,
the recording medium causing a computer to have a function as a flow rate control unit that controls a flow rate operation amount input to the flow rate control equipment by model predictive control based on a target concentration value of the raw material gas and a measured concentration value of the concentration measurement unit.
